(19) United States
(12) Patent Application Publication
(10) Pub. No.: US 2026/0304890 A1
(43) Pub. Date: Oct. 1, 2026

(54) INTERCONNECTS FOR COMPACT STANDARD CELLS

(71) Applicant: Intel Corporation, Santa Clara, CA (US)

(72) Inventor: Tuhin Guha Neogi, Beaverton, OR (US)

(73) Assignee: Intel Corporation, Santa Clara, CA (US)

(21) Appl. No.: 19/094,247

(22) Filed: Mar. 28, 2025

(51) Int. Cl. H10D 64/23; H10D 30/00; H10D 30/01; H10D 30/43; H10D 30/47; H10D 62/10; H10D 84/01; H10D 84/85

(52) U.S. Cl. CPC H10D 64/251; H10D 30/014; H10D 30/0191; H10D 30/43; H10D 30/502; H10D 62/121; H10D 84/0186; H10D 84/851; H10D 30/017; H10D 30/47

(57) ABSTRACT

Integrated circuit (IC) die with logic cells comprising transistors cross-coupled, at least in part, with an interconnect metallization structure that is on a backside of the IC die. CMOS pairs of gate-coupled transistors within a same logic cell may be coupled by both a layer of frontside metallization and a layer of backside metallization. Logic cell area may thereby be reduced for greater density without losing circuit functionality.

### BACKGROUND

For advanced integrated circuits (ICs), the introduction of back-side interconnect metallization counters a trend of increasing electrical resistance associated with dimensional scaling of power delivery through frontside interconnect metallization. Traditional frontside interconnect approaches to scaling of standard cells, which are the unitized blocks of logic design, are also becoming less effective with the increasing complexity of transistor structures. Many standard cells comprise cross-coupled pairs (CCP) of transistors with typical cross-coupling architectures relying on three, or more, frontside metal layers. For example, a frontside gate contact metallization layer, a metal zero (local interconnect) layer and a metal one layer may be required, in which case cross-coupled cells often occupy an area of at least two contacted poly pitches (2-CPP).

Since reductions in such cell area is often limited to a reduction in the gate electrode pitch (i.e., CPP), interconnect architectures that can reduce the CPP count of each cross couple to enable higher logic cell densities would be highly advantageous. For example, in a scan flop or multiplexer (MUX) that uses multiple cross couples, the IC die footprint area may be reduced by multiple CPPs.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a circuit diagram of cross-coupled CMOS pairs of transistors, which may be implemented a standard logic cell, in accordance with some embodiments;

FIG. 2 is a cell layout of cross-coupled transistor pairs implementing the circuit diagram illustrated in FIG. 1, in accordance with some embodiments;

FIG. 3 is a flow diagram illustrating fabrication of an IC die including logic cells with transistors that are cross-coupled with frontside and backside interconnect metallization, in accordance with some embodiments;

FIGS. 4 and 5 are cross-sectional views of an IC die structure comprising a logic cells with transistors cross-coupled with frontside and backside interconnect metallization, in accordance with some embodiments;

FIG. 6A is a plan view of a cross-coupled transistor pair layout, in accordance with some embodiments;

FIGS. 6B and 6C are cross-sectional views of cross-coupled transistor pairs shown in FIG. 6A, in accordance with some embodiments;

FIG. 7A is a plan view of a cross-coupled transistor pair layout, in accordance with some embodiments;

FIGS. 7B and 7C are cross-sectional views of cross-coupled transistor pairs shown in FIG. 7A, in accordance with some alternative embodiments;

FIGS. 8A and 8B are cross-sectional views of cross-coupled transistor pairs, in accordance with some embodiments;

FIGS. 9A and 9B are cross-sectional views of cross-coupled transistor pairs, in accordance with some alternative embodiments;

FIG. 10 illustrates a mobile computing platform and a data server machine employing an IC device including logic cells with transistor pairs cross-coupled in accordance with some embodiments; and

FIG. 11 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. In one example, two compositions that are substantially the same, have only incidental chemical variation. As another example, composition that is substantially a first constituent means the composition may further include <1% of any other constituent. A composition that is substantially first and second constituents means the composition may further include <1% of any constituent substituted for either the first or second constituent.

In accordance with embodiments herein, transistor pairs within a logic cell area of an integrated circuit are cross-coupled, at least in part, with backside interconnect metallization. In some advantageous embodiments, backside interconnect metallization supplements frontside interconnect metallization to cross-couple pairs of transistors. Cross-couple interconnect connections on the back side of an IC die can alleviate routing resources on the front side and enable more compact logic block sizes. For advanced libraries (e.g., at logic nodes 2nm and below), backside and frontside intra-cell signal interconnection in accordance with embodiments herein can free up frontside metal zero and metal one layer to provide more routing resources for inter-cell routing. As described further below, cross-coupling interconnect architectures described herein may reduce the area of a cross-coupled transistor pair to less than 2-CPP, and advantageously to 1-CPP. The cross-coupling interconnect architectures described herein are well-suited to pass-transistor based designs (e.g., PTL), such as for scan flops and MUXs.

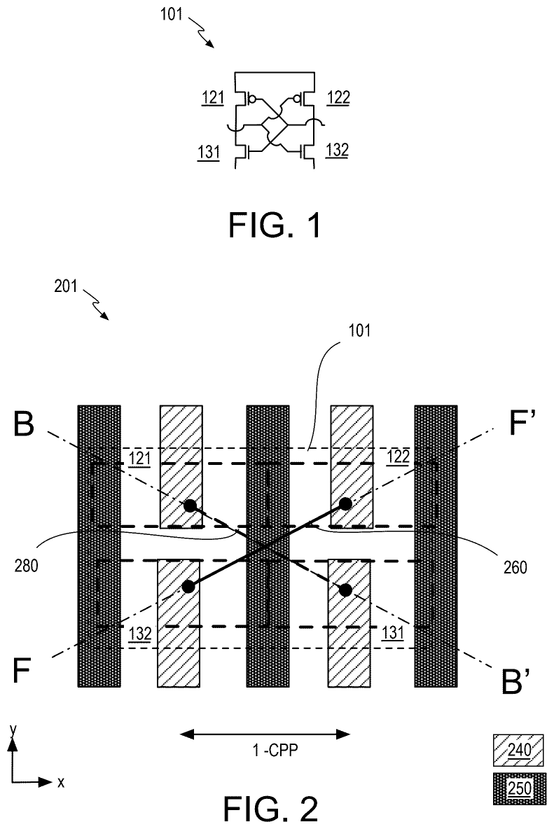

FIG. 1 illustrates a circuit diagram of cross-coupled CMOS transistor pairs 101, which may be implemented in various standard logic cells, in accordance with some embodiments. As shown, the cross-coupled pair includes four transistors comprising two p-channel (PMOS) load or “pull-up” transistors 121, 122 and two n-channel (NMOS) drive or “pull-down” transistors 131, 132. A gate electrode of each PMOS transistor is coupled to a gate electrode of each NMOS transistor. With source and drains of the PMOS and NMOS transistors further interconnected as shown, the cross-coupled pair may participate in implementing various logic operations executed by an IC.

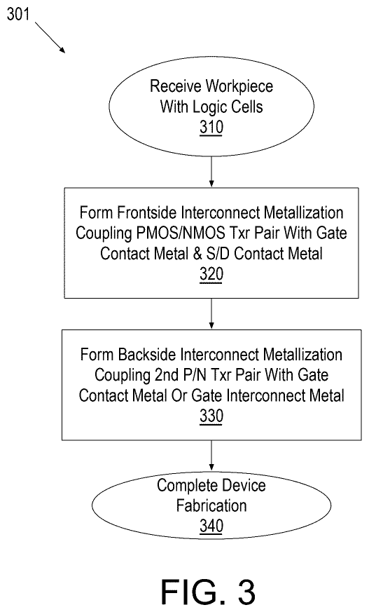

FIG. 2 is a logic cell 201 implementing the cross-coupled CMOS pairs 101 illustrated in FIG. 1, in accordance with some embodiments of an IC die structure that includes a plurality of such logic cells, for example arrayed over an area of the die. As shown, gate electrodes 240 are spaced apart by one gate or “poly” pitch (1-CPP). On opposite sides of gate electrodes 240 are stripes source/drain semiconductor material 250, which in this example are also at a same pitch as gate electrode 240. In FIG. 2, a cell area occupied by cross-coupled CMOS pairs 101 is highlighted by a dashed box. Within this cell area, PMOS transistor 121 occupies a first corner and PMOS transistor 122 occupies a second corner, denoted with heavy dashed line. NMOS transistors 132 and 131 occupy corresponding bottom corners, also denoted with heavy dashed line. In accordance with some exemplary embodiments, gate electrodes 240 of transistors 121 and 131 are coupled through backside interconnect metallization 280 represented as a B-B′ intra-cell coupling. Gate electrodes 240 of transistors 122 and 131 are coupled through frontside interconnect metallization 260 represented as a second F-F′ intra-cell coupling. Although the intra-cell gate couplings are illustrated as diagonals non-orthogonal to gate electrodes 240 and source/drain semiconductor stripes 250, these frontside or backside interconnects can be implemented with either a “Manhattan-style” orthogonal routing or actual diagonal (“non-Manhattan”) routing as embodiments herein are not limited in this respect. Although embodiments herein are illustrated to achieve a 1-CPP density in the x-dimension, other implementations may in the alternative drive similar layout area reduction in the y-dimension (i.e., cell height reduction). Still other embodiments may apply the principles described herein to reduce both cell width and cell height.

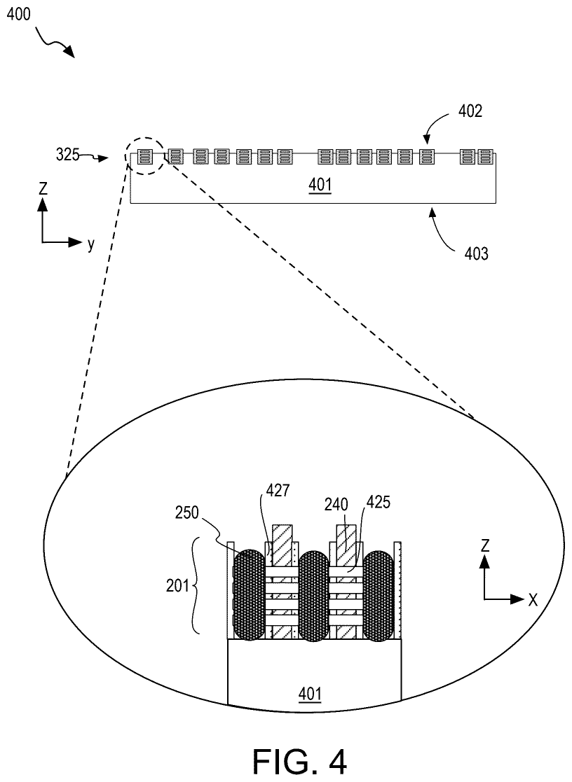

FIG. 3 is a flow diagram illustrating methods 301 for fabricating an IC die, chip, or chiplet with logic cells including CMOS transistor pairs cross-coupled through frontside and backside interconnect metallization, in accordance with some exemplary embodiments. In some examples, methods 301 are performed on a 250-450 mm diameter wafer.

Methods 301 begin at input 310 with receipt of a workpiece that includes a device layer or is suitable for the fabrication of a device layer. The device layer may comprise field effect transistor (FET) structures, or other integrated electrical and/or optical (photonic) device structures. The device layer includes logic cells, at least some of which are to comprise cross-coupled CMOS transistors. In some embodiments, the logic cells comprise a scan flop. In other embodiments the logic cells comprise a MUX. In further embodiments, the device layer includes power circuitry, for example to supply power into the logic cells.

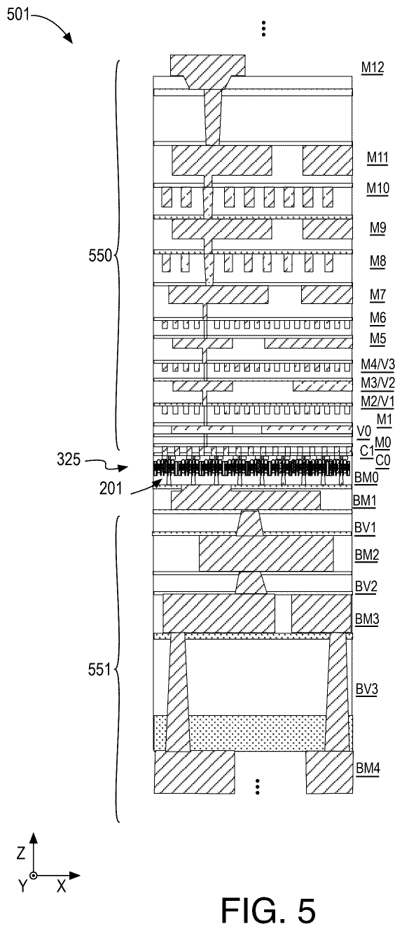

FIG. 4 is a cross-sectional view of an exemplary workpiece comprising an IC die structure 400 including a device layer 325 on a substrate material 401. In some embodiments, substrate material 401 is monocrystalline material, such as monocrystalline silicon, monocrystalline germanium, a monocrystalline silicon-germanium alloy, or a monocrystalline III-V material. One or more device material layers may be over substrate material 401. In the example further illustrated in expanded view of FIG. 4, device layer 325 comprises cell 201 implemented with nanosheet transistors comprising vertically stacked channel material 425. device layer 325 comprises transistor structures of logic cell 201. In the illustrated nanosheet architecture example, the transistor structures comprises vertical stacks of channel material 425. Of course, the transistor structures may also have less complex architectures, such as a single finFET channel device, a planar channeled device, etc.

Independent of the transistor architecture, transistor channel material 425 may be associated with N-type (NMOS) transistor structures and/or P-type (PMOS) transistor structures. Channel material 425 may have any composition suitable for a channel of a field effect transistor (FET) and advantageously has a composition similar to, or substantially the same as, the composition of substrate material 401. In some examples where substrate material 401 is monocrystalline silicon, channel material 425 is also substantially pure silicon. However, in other embodiments where substrate material 401 is monocrystalline silicon, channel material 425 comprises germanium (e.g., SiₓGe_{1-X}, GeₓSn_{1-X}, or substantially pure Ge). In some other embodiments, channel material 425 includes a transition metal and a chalcogen.

Channel material 425 is advantageously crystalline. Although the crystalline semiconductor includes polycrystalline thin film material, in some embodiments channel material 425 is substantially monocrystalline. In some embodiments where channel material 425 is substantially pure silicon, the crystallinity of channel material 425 is cubic with a top surface having a crystallographic orientation of (100), (111), or (110). However, other crystallographic orientations are also possible. In other embodiments, channel material 425 may be polycrystalline or amorphous, for example in certain metal chalcogen and/or metal oxide embodiments.

Logic cell 201 further includes dielectric sidewall spacer dielectric material 427 that surrounds underlying channel material 425. Sidewall spacer dielectric material 427 may comprise a silicon-based dielectric (e.g., SiO₂, Si₃N₄, SiON, etc.). Cell 201 further includes source and drain semiconductor material 250. PMOS and NMOS source and drain semiconductor material 250 may be separately grown, for example. In some PMOS transistor embodiments, source and drain semiconductor material 250 is a Si₁₋ₓGeₓ alloy further including acceptor impurities imparting p-type electrical conductivity. In some NMOS transistor embodiments, source and drain semiconductor material 250 is substantially pure silicon (i.e., only Group IV element is silicon) further including donor impurities imparting n-type electrical conductivity. Accordingly, except for the greater impurity concentration, source and drain semiconductor material 250 may have substantially the same chemical composition as substrate (semiconductor) material 401.

Gate material 240 is adjacent to at least a sidewall of channel material 425 and may further wrap substantially around a nanowire or nanoribbon of channel material 425. Although not illustrated, gate material 240 is electrically coupled to channel material 425 through one or more layers of gate insulator material, which may be any high-k gate dielectric such as HfO₂, Al₂O₃, for example.

Returning to FIG. 1, methods 301 continue at block 320 where frontside interconnect metallization levels are fabricated over a front side of an IC die device layer, and more particularly over a front side of a logic cell. Frontside interconnect routing metallization may include any number of metallization levels. However, in exemplary embodiments no more than two frontside interconnect routing levels couple a first PMOS transistor of one logic cell with a first NMOS transistor of the same logic cell. In advantageous embodiments, the intra-cell coupling of the first CMOS transistor pair is implemented with only a gate contact metal and a source/drain contact metal, for example as described further below.

At block 330, a backside interconnect metallization structure is fabricated over a back side of an IC die device layer, and more particularly over a backside of a logic cell. Backside interconnect routing metallization may also include any number of metallization levels. However, in exemplary embodiments no more than two backside interconnect routing levels cross-couple a second PMOS transistor with a second NMOS transistor of the same logic cell. In advantageous embodiments, the intra-cell coupling of the second CMOS transistor pair is implemented with only a gate contact metal or a gate interconnect metal, for example as described further below.

Methods 301 then end at output 340 with the completion of IC die fabrication. The IC die may then be singulated from the workpiece, and packaged according to any known techniques. The packaged IC die may then be assembled into a computer system or platform, such as a mobile device or data server platform, for example.

FIG. 5 further illustrates a cross-sectional view of an IC die structure 501 comprising device layer 325 between frontside interconnect metallization structure 550 and backside interconnect metallization structure 551. In the illustrated example, device layer 325 (and comprising many logic cells 201) is embedded within one or more layers of dielectric material between a backside metal zero (BM0) and a frontside contact metal “zero” (C0), which in some examples is a source/drain contact metal while a gate electrode is contacted with a frontside contact metal “one” (C1).

Frontside interconnect metallization structure 550 and backside interconnect metallization structure 551 may each comprise any number of metallization levels within any thickness of dielectric material. Frontside and backside interconnect metallization structures may be fabricated according to any known techniques (e.g., single or dual damascene, etc.), as embodiments herein are not limited in this respect. In some embodiments, some frontside metallization features are electrically coupled to at least drain semiconductor material of transistor structures within device layer 325 while other frontside metallization features may be coupled to gate electrode material. In further embodiments, some backside metallization features are electrically couple to at least some source semiconductor material of transistor structures within device layer 325. Such electrical interconnection may be found in power delivery circuitry of an IC die while frontside and backside metallization structures 550, 551 may further comprise metallization features coupled with transistor structures of logic cell circuitry, as described below.

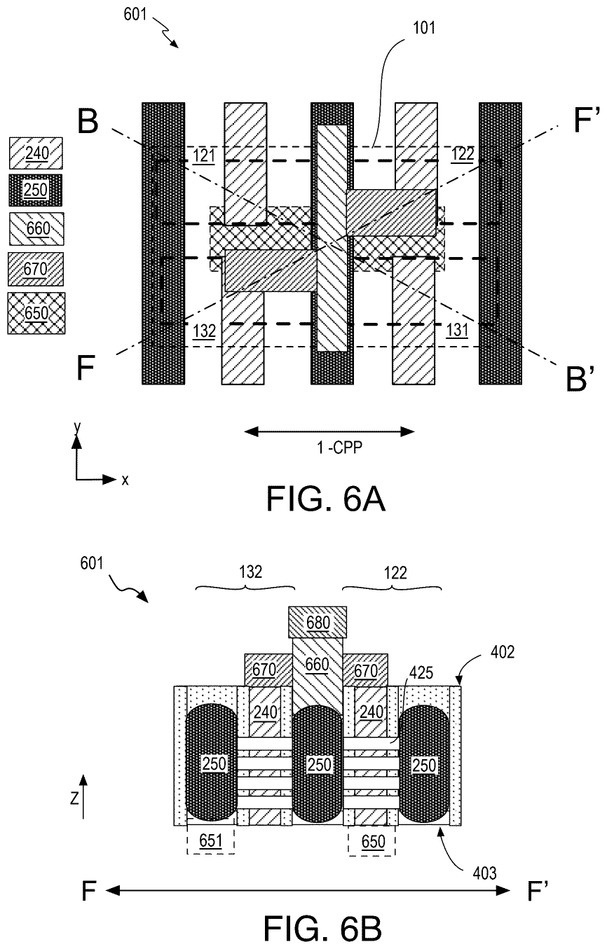

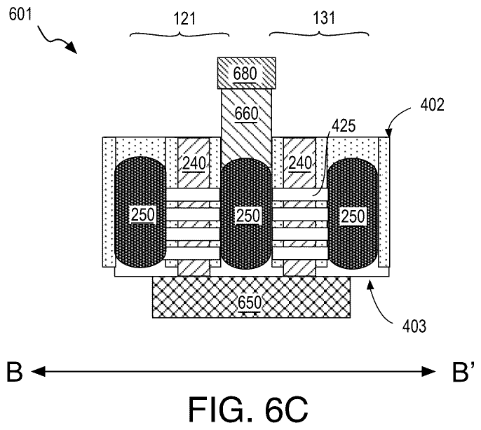

FIG. 6A is a plan view of a cross-coupled transistor pairs 601, in accordance with some embodiments. FIG. 6B illustrates one example of front-side interconnect level coupling F-F′, as introduced in FIG. 2, while FIG. 6C illustrates one example of back-side interconnect level coupling B-B′.

Referring first to FIG. 6A, cross-coupled transistor pairs 601 include transistor 122 and transistor 132. Noting the F-F′ coupling is illustrated along a diagonal, a non-orthogonal slice through each of transistors 122 and 132 is illustrated in FIG. 6B for the sake of clarity in their electrical interconnection. As shown, frontside interconnect metallization over frontside surface 402 comprises diffusion (s/d) contact metal 660, which is over, and in direct contact with, a stripe of source/drain semiconductor material 250 located between channel material 425 of each of transistors 122 and 132. Frontside interconnect metallization further comprises gate contact metal 670 over, and in direct contact with, gate electrodes 240 of both transistor 122 and transistor 132. Gate contact metal 670 is further in direct contact with diffusion contact metal 660 such that, together, gate contact metal 670 and diffusion contact metal 660 form a frontside route within an interior of a logic cell that electrically connects gate electrodes 240 of transistors 122 and 132.

In FIG. 6A-6C, the illustrated layers of frontside metallization have different field lines to emphasize their structural relationships. The chemical compositions of gate contact metal 670 and contact metal 660 may be the same or different. Similarly, the chemical composition of gate contact metal 670 may be the same or different than the chemical composition of gate electrode 240 as embodiments are not limited in this respect. In the illustrated embodiment, at least gate contact metal 670 may be considered a local interconnect level, connecting gate electrode 240 to diffusion contact metal 660. Gate contact metal 670 and diffusion contact metal 660 are therefore distinguished from a first via metallization 680, which lands on diffusion contact metal 660. Another via metallization (not depicted) may similarly land on gate contact metal 670. In the example illustrated in FIG. 6B, there is no backside interconnect metallization within the depicted portion of a logic cell. However, alternative embodiments may include backside metallization features 650, 651, which may be present in alternative embodiments but are illustrated in dashed line to emphasize such features may be absent. For example, in contact with one or more terminal of transistor 122 and/or transistor 132. Such backside metallization features (e.g., 650, 651) may have various functions, but in exemplary embodiments backside metallization features do not form a route that electrically couples together gate electrodes 240 of transistors 122 and 132.

FIG. 6A further illustrates cross-coupling of transistor 121 and transistor 131 with gate their electrodes coupled through backside interconnect metallization. The illustrated B-B′ coupling is similarly on a diagonal, intersecting the F-F′ coupling substantially as introduced in FIG. 2. The B-B′ coupling is therefore depicted in FIG. 6C along a non-orthogonal slice through each of transistors 121 and 131 for the sake of clarity in their electrical interconnection. In the illustrated example, backside interconnect metallization over backside surface 403 comprises backside gate contact metal 650. In this examples, a single body of backside gate contact metal 650 is over, and in direct contact with, gate electrode 240 of each of transistors 121 and 131. The chemical composition of backside gate contact metal 650 may be the same as that of gate electrode 240, or may have a different composition as embodiments are not limited in this respect. In the illustrated embodiment, backside gate contact metal 650 may be considered another local, intra-cell interconnect level, connecting together gate electrodes 240 to complete the cross-coupling of the gate electrodes of first transistor pairs (FIG. 6B) and second transistor pair (FIG. 6C).

In the example illustrated by FIG. 6C, frontside interconnect metallization comprising diffusion contact metal 660 and via metal 680 is also within the depicted portion of the logic cell and such frontside metallization features may have various functions. However, in exemplary embodiments frontside metallization features do not form a route that electrically couples together gate electrodes 240 of transistors 121 and 131.

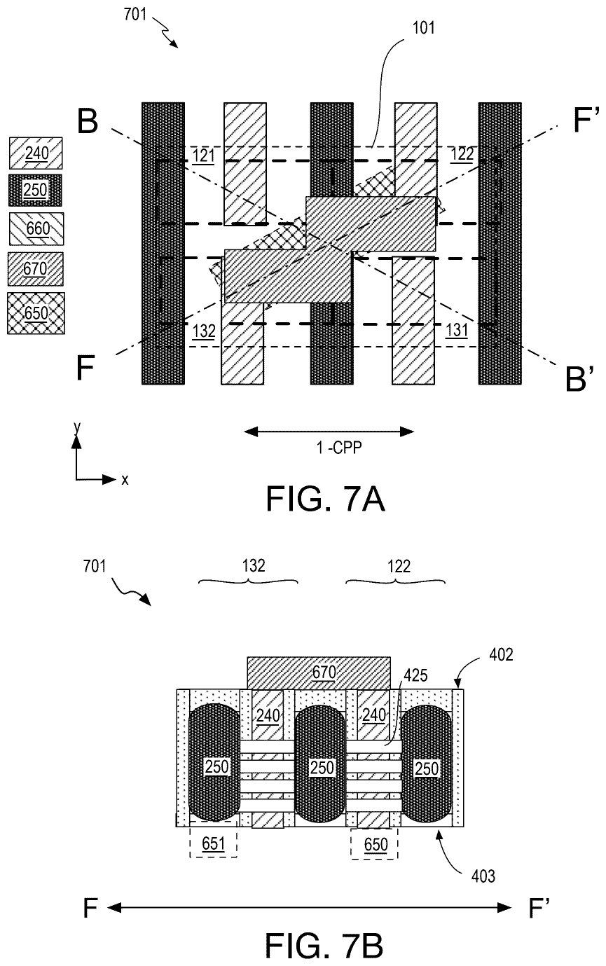

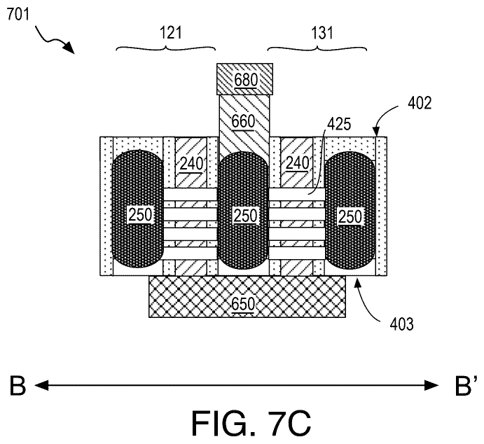

FIG. 7A is a plan view of a cross-coupled transistor pairs 701, in accordance with some alternative embodiments. FIGS. 7B and 7C are again cross-sectional views of cross-coupled transistor pairs 701. FIG. 7A again illustrates a example of front-side interconnect level coupling F-F′, as introduced in FIG. 2, while FIG. 7B similarly illustrates another example of back-side interconnect level coupling B-B′.

Referring first to FIG. 7A, cross-coupled transistor pair 701 includes transistor 122 and transistor 132. In this example backside gate contact metal 650 has a diagonal (i.e., non-Manhattan) layout. Along the F-F′ line shown in FIG. 7B, frontside interconnect metallization over frontside surface 402 comprises gate contact metal 670 over, and in direct contact with, gate electrodes 240 of both transistor 122 and transistor 132. The route of gate contact metal 670 does not intersect (i.e., contact) any diffusion (s/d) contact metal (not depicted), which may be over, and in direct contact with, the stripe of source/drain semiconductor material 250 located between transistors 122 and 132. Diffusion contact metal may instead be out of the plane of FIG. 7B and therefore not contribute to the interconnection of gate electrodes of transistors 122 and 132.

In FIG. 7A-7C, gate contact metal 670 is illustrated with different field lines than gate metal 240 to emphasize their structural relationship. The chemical compositions of gate contact metal 670 and gate metal 240 may be the same or different as embodiments are not limited in this respect. In the illustrated embodiment, gate contact metal 670 may again be considered a local (intra-cell) interconnect level. In the context of FIG. 7B, gate contact metal 670 is again to be distinguished from a first frontside via metallization (not depicted), which may land on gate contact metal 670. In the example illustrated by FIG. 7B, there is again no backside interconnect metallization within the depicted portion of the logic cell. However, alternative embodiments may include backside metallization features 650, 651, which may be present in alternative embodiments but are illustrated in dashed line to emphasize such features may be absent. For example, in contact with one or more terminal of transistor 122 and/or transistor 132. Such backside metallization features may have various functions, but in exemplary embodiments backside metallization features do not form a route that electrically couples together gate electrodes 240 of transistors 122 and 132.

FIG. 7C illustrates cross-coupled transistor pair 701 further includes transistor 121 and transistor 131 that have their gate electrodes coupled through backside interconnect metallization. In the illustrated example, backside interconnect metallization over backside surface 403 again comprises backside gate contact metal 650 over, and in direct contact with, gate electrode 240 of each of transistors 121 and 131. Hence, backside gate contact metal 650 is again connecting together gate electrodes 240 to complete the cross-coupling of the gate electrodes of first transistor pairs (FIG. 7B) and second transistor pair (FIG. 7C). However, as shown in FIG. 7A, gate contact metal 650 is in this example non-orthogonal to a length and width of one or more transistor features (e.g., channel material 425).

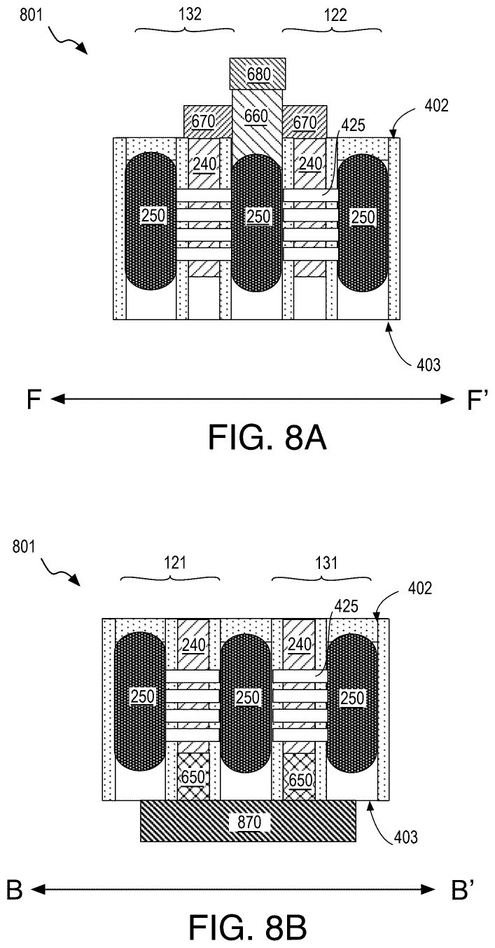

Although FIG. 6A-7C illustrate a few examples of cross-coupled transistor pairs of a logic cell. Embodiments herein may be alternatively implemented to accommodate variations in transistor architecture. For example, two or more levels of backside metal may be utilized for coupling transistor terminals (e.g., gate electrodes) within a single logic cell where needed to accommodate transistor structures. FIGS. 8A and 8B are cross-sectional views of cross-coupled transistor pairs 801 in accordance with some alternative embodiments.

Referring first to FIG. 8A, cross-coupled transistor pairs 801 again includes transistor 122 and transistor 132. In this example, frontside interconnect metallization over frontside surface 402 again comprises gate contact metal 670 over, and in direct contact with, gate electrodes 240 of both transistor 122 and transistor 132. Similar to cross-coupled transistor pairs 601 (FIG. 6A) the route of gate contact metal 670 again intersects (i.e., contacts) diffusion (s/d) contact metal 680, which is over, and in contact with, source/drain semiconductor material 250 located between transistors 122 and 132.

Although the frontside intra-cell interconnect metallization depicted in FIG. 8A is substantially the same as that depicted in FIG. 6B, transistor architecture varies at least with respect to source/drain semiconductor material 250. As shown in FIG. 8A, source/drain semiconductor material 250 has physically larger epitaxial growth, which extends to a depth toward backside surface 403 that exceeds the depth of gate electrodes 240. As such, backside interconnect metallization routing within a logic cell illustrated in FIG. 8B comprises backside gate contact metal 650 and backside via metal 870, which is in direct contact with gate contact metal 650. Gate contact metal 650 is of sufficient lateral width to electrically couple together the gate electrodes 240 of both transistor 121 and transistor 131 through the two discrete bodies of gate contact metal 650.

In FIG. 8B, backside via metal 870 is illustrated with different field lines than backside gate contact metal 650 to emphasize their structural relationship and their compositions may be the same or different as embodiments are not limited in this respect. In the illustrated embodiment, via metal 870 may be considered a local (intra-cell) interconnect level spanning a physical distance of a logic cell occupied by underlying source/drain semiconductor material 250.

In FIG. 8B, there is again no frontside interconnect metallization within the illustrated portion of the logic cell. However, alternative embodiments may include frontside metallization features (not depicted). For example, frontside metallization may be in contact with one or more terminal of transistor 121 and/or transistor 131. Such frontside metallization features may have various functions, but in exemplary embodiments frontside metallization features do not form a route that electrically couples together gate electrodes 240 of transistors 121 and 131.

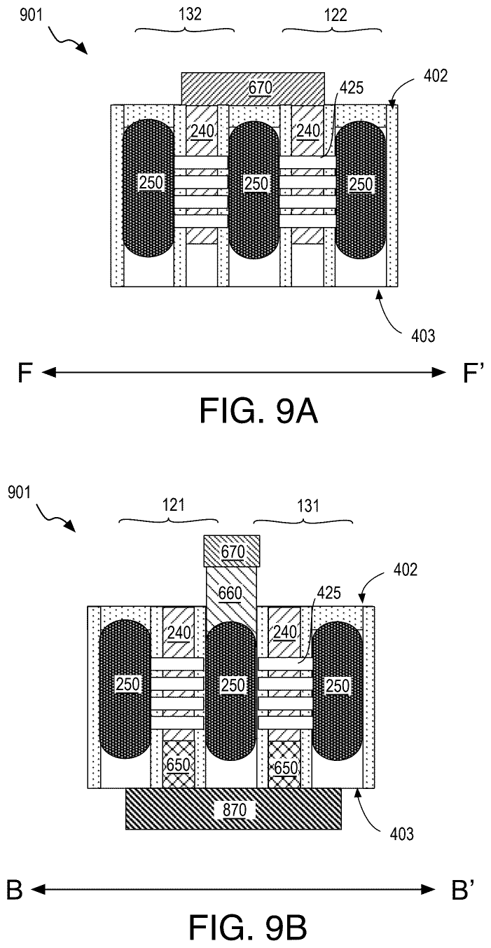

FIGS. 9A and 9B are cross-sectional views of cross-coupled transistor pairs 901, in accordance with some alternative embodiments wherein a backside of source/drain epitaxy is again significantly deeper than the backside of gate electrode 240. Intra-cell interconnection of a transistor pair 122 and 132 is substantially the same as shown in FIG. 7B. In FIG. 9B, backside coupling of the gate electrodes of transistors 121 and 131 is similar to FIG. 7C, but comprises two separate bodies of backside gate contact metal 650, and a backside via metal 670 that directly contacts both bodies of gate contact metal 650.

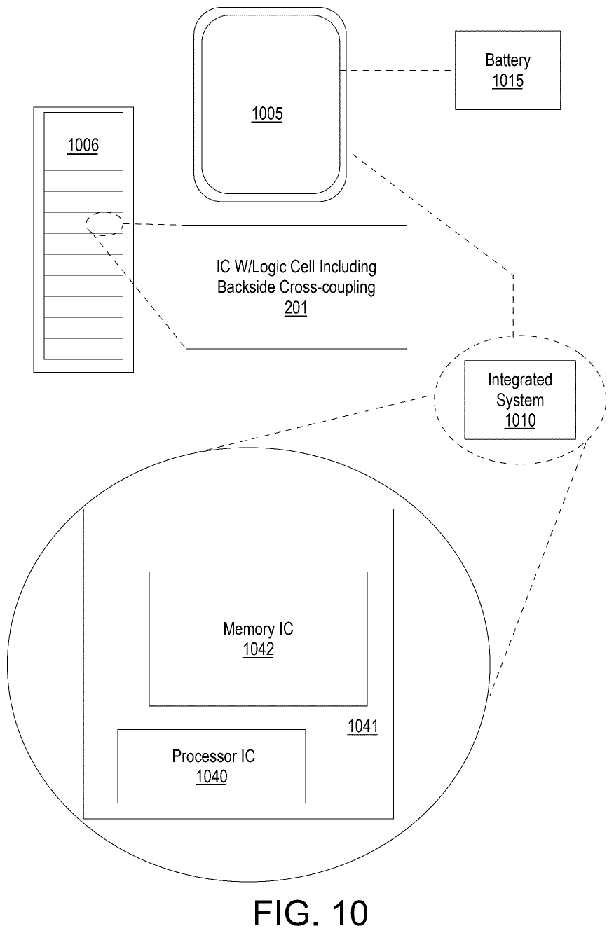

The various logic cells, and methods of cross-coupling CMOS transistor pairs within the logic cells, described herein may be integrated into a wide variety of IC packages and systems that include such IC packages. FIG. 10 illustrates a mobile computing platform 1005 and a server machine 1006, each employing at least one IC die that includes a logic cell further including transistor pairs cross-coupled, at least in part, with backside interconnect metallization, for example as described elsewhere herein.

Server machine 1006 may be any commercial server, for example including any number of high-performance computing platforms disposed within a rack and networked together for electronic data processing, such as large language model (LLM) processing. The mobile computing platform 1005 may be any portable device configured for each of electronic data display, electronic data processing, wireless electronic data transmission, or the like. For example, the mobile computing platform 1005 may be any of a tablet, a smart phone, laptop computer, etc., and may include a display screen (e.g., a capacitive, inductive, resistive, or optical touchscreen), an integrated system 1010, and a battery 1015.

As illustrated in the expanded view of FIG. 10, mobile computing platform 1005 comprises an integrated system 1010 hosting a package 1041 further hosting a processor IC 1040 and a memory IC 1042. At least one of processor IC 1040 or memory IC 1042 includes a logic cell with transistor pairs cross-coupled, at least in part, with backside interconnect metallization, for example as described elsewhere herein.

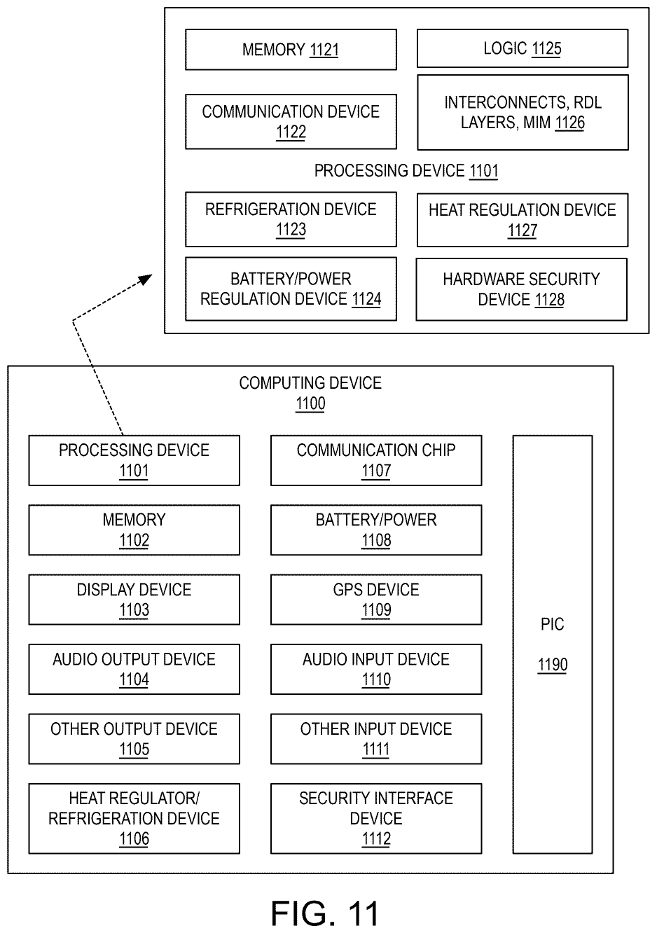

FIG. 11 is a block diagram of a cryogenically cooled computing device 1100 in accordance with some embodiments. For example, one or more components of computing device 1100 may include an IC die comprising logic cells including transistor pairs that have their gate electrodes cross-coupled, at least in part, with backside interconnect metallization, for example as described elsewhere herein. A number of components are illustrated in FIG. 11 as included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled.

Computing device 1100 may include a processing device 1101 (e.g., one or more processing devices). As used herein, the term processing device or processor indicates a device that processes electronic data from registers and/or memory to transform that electronic data into other electronic data that may be stored in registers and/or memory. Processing device 1101 may include a memory 1121, a communication device 1122, a refrigeration/active cooling device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1101 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1121 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed elsewhere herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). Communication chip 1107 may operate in accordance with other wireless protocols in other embodiments. Computing device 1100 may include an photonic IC (PIC) 1190 to facilitate optical communications. Communication chip 1107 may therefore manage optical (fiber) communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a global positioning system (GPS) device 1109 (or corresponding interface circuitry, as discussed above). GPS device 1109 may be in communication with a satellite-based system and may receive a location of computing device 1100, as known in the art.

Computing device 1100 may include another output device 1105 (or corresponding interface circuitry, as discussed above). Examples include an audio codec, a video codec, a printer, a wired or wireless transmitter for providing information to other devices, or an additional storage device.

Computing device 1100 may include another input device 1111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, managing access lists, malware detection, or spyware detection. In some examples, security interface device 1112 comprises OTP ROM.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments described above, but can instead be practiced with modification and alteration without departing from the scope of the appended claims. For example, the above embodiments may include specific combinations of features as further provided below.

In first examples, an apparatus comprises a device layer comprising a logic cell with a first transistor pair and a second transistor pair, a first interconnect metallization structure over a frontside of the device layer, the first interconnect metallization structure interconnecting together first terminals of the first pair of transistors, and a second interconnect metallization structure over a backside of the device layer, the second interconnect metallization structure interconnecting together first terminals of the second pair of transistors.

In second examples, for any of the first examples the first transistor pair comprises an NMOS transistor and a PMOS transistor, and the second transistor pair comprises an NMOS transistor and a PMOS transistor.

In third examples, for any of the first through second examples the first interconnect metallization couples together a gate electrode of each the first pair of transistors, and the second interconnect metallization couples together a gate electrode of each the second pair of transistors.

In fourth examples, for any of the third examples the first interconnect metallization comprises a frontside gate contact metal that is in direct contact with a frontside of the gate electrode of each of the first pair of transistors; and the second interconnect metallization comprises a backside gate contact metal that is in direct contact with a backside of the gate electrode of each of the second pair of transistors.

In fifth examples, for any of the fourth examples the first interconnect metallization comprises a frontside source/drain diffusion contact metal, and the frontside gate contact metal in contact with the gate electrode of one of the first pair of transistors is electrically coupled by the frontside source/drain diffusion contact metal to the frontside gate contact metal in contact with the gate electrode of another of the first pair of transistors.

In sixth examples, for any of the fourth through fifth examples a single body of the frontside gate contact metal spans a length of the logic cell and is in direct contact with the frontside of the gate electrode of each of the first pair of transistors

In seventh examples, for any of the fourth through sixth examples, a single body of the backside gate contact metal spans a lateral distance of the logic cell and is in direct contact with a first gate electrode of one of the second pair of transistors and is in direct contact with a second gate electrode of another of the second pair of transistors.

In eighth examples, for any of the fourth through seventh examples the second interconnect metallization comprises a first body of backside gate contact metal coupled to a first gate electrode of one of the second pair of transistors, a second body of backside gate contact metal coupled to a first gate electrode of one of the second pair of transistors, and a single body of a second layer of backside metal spanning a lateral distance of the logic cell and is in direct contact with the single body of backside gate contact metal and in direct contact with the second body of backside gate contact metal.

In ninth examples, for any of the eighth examples source/drain semiconductor material is between the first body of backside gate contact metal and second body of the backside gate contact metal.

In tenth examples, for any of the first through ninth examples the logic cell comprises first cross-coupled transistor pairs of a scan flop or multiplexer circuit.

In eleventh examples, an integrated circuit (IC) logic cell comprises a first pair of PMOS and NMOS transistors cross-coupled with a second pair PMOS and NMOS transistors, and an interconnect metallization structure on a back side of the transistors, wherein the interconnect metallization structure interconnects gate electrodes of at least one of the first or second pairs of PMOS and NMOS transistors.

In twelfth examples, for any of the eleventh examples an area occupied by the pair of PMOS and NMOS transistors and the interconnect metallization structure has a width in a first dimension that is less than twice a pitch of the gate electrodes in the first dimension.

In thirteenth examples, for any of the twelfth examples the width in the first dimension is no more than the pitch of the gate electrodes in the first dimension.

In fourteenth examples, for any of the thirteenth examples the interconnect metallization structure interconnects gate electrodes of the first pair of PMOS and NMOS transistors, the logic cell further comprises a second interconnect metallization structure on a front side of the transistors, and the second interconnect metallization structure interconnects gate electrodes of the second pair of the PMOS and NMOS transistors.

In fifteenth examples, for any of the twelfth through fourteenth examples the interconnect metallization structure comprises a metal in direct contact with a backside of the gate electrodes of at least the first pair of PMOS and NMOS transistors

In sixteenth examples, for any of the twelfth through fifteenth examples the metal in direct contact with a backside of the gate electrodes is a single body of the metal spanning the pitch of the gate electrodes.

In seventeenth examples, a method comprises receiving an integrated circuit workpiece comprises a logic cell comprising a plurality of transistors, forming a first interconnect metallization structure over a first side of the integrated circuit workpiece, wherein the first interconnect metallization structure couples together gate electrodes of a first PMOS and NMOS transistor pair in the logic cell, and forming a second interconnect metallization structure over a first side of the integrated circuit workpiece, wherein the second interconnect metallization structure couples together gate electrodes of a second PMOS and NMOS transistor pair in the logic cell.

In eighteenth examples, for any of the seventeenth example forming the second interconnect metallization structure comprises forming a single body of metal in direct contact with a backside of the gate electrodes of the second PMOS and NMOS transistor pair.

In nineteenth examples, for any of the seventeenth through eighteenth examples forming the second interconnect metallization structure comprises forming a first body of metal in direct contact with a backside of the gate electrode of a first one of the second PMOS and NMOS transistor pair, forming a second body of metal in direct contact with a backside of the gate electrode of a second one of the second PMOS and NMOS transistor pair, and forming a third body of metal in direct contact with the first body of metal and in direct contact with the second body of metal.

In twentieth examples, for any of the nineteen examples the first body of metal and second body of metal are within a first layer of the metallization structure, and the third body of metal is within a second layer of the metallization structure.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should, therefore, be determined with reference to the appended claims, along with the full scope of equivalents to which such claims are entitled.

What is claimed is:

1. An apparatus, comprising:
a device layer comprising a logic cell with a first transistor pair and a second transistor pair;
a first interconnect metallization structure over a frontside of the device layer, the first interconnect metallization structure interconnecting together first terminals of the first pair of transistors; and
a second interconnect metallization structure over a backside of the device layer, the second interconnect metallization structure interconnecting together first terminals of the second pair of transistors.

2. The apparatus of claim 1, wherein:
the first transistor pair comprises an NMOS transistor and a PMOS transistor; and
the second transistor pair comprises an NMOS transistor and a PMOS transistor.

3. The apparatus of claim 2, wherein:
the first interconnect metallization couples together a gate electrode of each the first pair of transistors; and
the second interconnect metallization couples together a gate electrode of each the second pair of transistors.

4. The apparatus of claim 3, wherein:
the first interconnect metallization comprises a frontside gate contact metal that is in direct contact with a frontside of the gate electrode of each of the first pair of transistors; and
the second interconnect metallization comprises a backside gate contact metal that is in direct contact with a backside of the gate electrode of each of the second pair of transistors.

5. The apparatus of claim 4, wherein:
the first interconnect metallization comprises a frontside source/drain diffusion contact metal; and
the frontside gate contact metal in contact with the gate electrode of one of the first pair of transistors is electrically coupled by the frontside source/drain diffusion contact metal to the frontside gate contact metal in contact with the gate electrode of another of the first pair of transistors.

6. The apparatus of claim 4, wherein a single body of the frontside gate contact metal spans a length of the logic cell and is in direct contact with the frontside of the gate electrode of each of the first pair of transistors.

7. The apparatus of claim 4, wherein a single body of the backside gate contact metal spans a lateral distance of the logic cell and is in direct contact with a first gate electrode of one of the second pair of transistors and is in direct contact with a second gate electrode of another of the second pair of transistors.

8. The apparatus of claim 4, wherein the second interconnect metallization comprises:
a first body of backside gate contact metal coupled to a first gate electrode of one of the second pair of transistors;
a second body of backside gate contact metal coupled to a first gate electrode of one of the second pair of transistors; and
a single body of a second layer of backside metal spanning a lateral distance of the logic cell and is in direct contact with the single body of backside gate contact metal and in direct contact with the second body of backside gate contact metal.

9. The apparatus of claim 8, wherein source/drain semiconductor material is between the first body of backside gate contact metal and second body of the backside gate contact metal.

10. The apparatus of claim 1, wherein the logic cell comprises first cross-coupled transistor pairs of a scan flop or multiplexer circuit.

11. An integrated circuit (IC) logic cell, comprising:
a first pair of PMOS and NMOS transistors cross-coupled with a second pair PMOS and NMOS transistors; and
an interconnect metallization structure on a back side of the transistors, wherein the interconnect metallization structure interconnects gate electrodes of at least one of the first or second pairs of PMOS and NMOS transistors.

12. The IC logic cell of claim 11, wherein an area occupied by the pair of PMOS and NMOS transistors and the interconnect metallization structure has a width in a first dimension that is less than twice a pitch of the gate electrodes in the first dimension.

13. The IC logic cell of claim 12, wherein the width in the first dimension is no more than the pitch of the gate electrodes in the first dimension.

14. The IC logic cell of claim 13, wherein:
the interconnect metallization structure interconnects gate electrodes of the first pair of PMOS and NMOS transistors;
the logic cell further comprises a second interconnect metallization structure on a front side of the transistors; and
the second interconnect metallization structure interconnects gate electrodes of the second pair of the PMOS and NMOS transistors.

15. The IC logic cell of claim 12, wherein the interconnect metallization structure comprises a metal in direct contact with a backside of the gate electrodes of at least the first pair of PMOS and NMOS transistors.

16. The IC logic cell of claim 12, wherein the metal in direct contact with a backside of the gate electrodes is a single body of the metal spanning the pitch of the gate electrodes.

17. A method, comprising:
receiving an integrated circuit workpiece comprises a logic cell comprising a plurality of transistors;
forming a first interconnect metallization structure over a first side of the integrated circuit workpiece, wherein the first interconnect metallization structure couples together gate electrodes of a first PMOS and NMOS transistor pair in the logic cell; and
forming a second interconnect metallization structure over a first side of the integrated circuit workpiece, wherein the second interconnect metallization structure couples together gate electrodes of a second PMOS and NMOS transistor pair in the logic cell.

18. The method of claim 17, wherein forming the second interconnect metallization structure comprises forming a single body of metal in direct contact with a backside of the gate electrodes of the second PMOS and NMOS transistor pair.

19. The method of claim 17, wherein forming the second interconnect metallization structure comprises:
forming a first body of metal in direct contact with a backside of the gate electrode of a first one of the second PMOS and NMOS transistor pair;
forming a second body of metal in direct contact with a backside of the gate electrode of a second one of the second PMOS and NMOS transistor pair; and
forming a third body of metal in direct contact with the first body of metal and in direct contact with the second body of metal.

20. The method of claim 19, wherein the first body of metal and second body of metal are within a first layer of the metallization structure, and the third body of metal is within a second layer of the metallization structure.
